(19) United States
(12) Patent Application Publication
(10) Pub. No.: US 2025/0365895 A1
(43) Pub. Date: Nov. 27, 2025

(54) IMMERSION COOLING SYSTEM

(71) Applicant: AEWIN TECHNOLOGIES CO., LTD., New Taipei City (TW)

(72) Inventor: Cheng-En LIU, New Taipei City (TW)

(21) Appl. No.: 19/016,984

(22) Filed: Jan. 10, 2025

(30) Foreign Application Priority Data
May 23, 2024 (TW) 113119162

(51) Int. Cl. H05K 7/20

(52) U.S. Cl. CPC H05K 7/20327; H05K 7/203; H05K 7/20318

(57) ABSTRACT

An immersion cooling system is provided and includes a box body, a condensing unit, a flow guiding structure and a heat dissipation medium. The box body has a first accommodating space, a second accommodating space and a water collecting tank connected to the second accommodating space. The condensing unit is arranged in the second accommodating space. The flow guiding structure is located below the condensing unit. The heat dissipation medium is accommodated in the first accommodating space and the water collecting tank and is able to flow on the flow guiding structure.

### CROSS-REFERENCE TO RELATED APPLICATIONS

This application claims priority to Taiwan Application Serial No. 113119162, filed on May 23, 2024. The entirety of the above-mentioned patent application is hereby incorporated by reference herein and made a part of this specification.

### BACKGROUND

### 1. Technical Field

The present disclosure relates to a cooling system, and more particularly, to an immersion cooling system that can accelerate the separation of water in a heat dissipation medium.

### 2. Description of Related Art

The two-phase immersion cooling method utilizes the phase conversion between the gas state and the liquid state of the water-cooling liquid to take away heat. Specifically, the water-cooling liquid in the sealed tank absorbs the heat energy generated by the heating element and gasifies, then the gasified water-cooling liquid condenses on a condenser after contacting the condenser, and droplets of the water-cooling liquid condensed on the condenser fall back into the water-cooling liquid by gravity, thereby achieving the heat dissipation effect of the heating element via this circulation.

However, in the existing two-phase immersion cooling method, when the equipment is opened for maintenance, atmospheric moisture is easily mixed into the sealed tank and evaporates and condenses together with the water-cooling liquid, causing the water-cooling liquid to be doped with atmospheric moisture, thereby causing a reduction in evaporation and condensation efficiency. Moreover, too high water content in the water-cooling liquid may cause equipment damage.

### SUMMARY

The present disclosure provides an immersion cooling system, which comprises: a box body having a first accommodating space, a second accommodating space and a water collecting tank connected to the second accommodating space; a condensing unit arranged in the second accommodating space; a flow guiding structure located below the condensing unit; and a heat dissipation medium accommodated in the first accommodating space and the water collecting tank, wherein the heat dissipation medium absorbs thermal energy in the first accommodating space and then gasifies and is introduced into the second accommodating space, wherein the gasified heat dissipation medium is condensed and liquefied via heat exchange in the condensing unit, and the liquefied heat dissipation medium flows on the flow guiding structure to separate water contained in the liquefied heat dissipation medium.

In the aforementioned immersion cooling system, the flow guiding structure includes a first flow guiding unit and at least one second flow guiding unit, the first flow guiding unit is disposed in the second accommodating space, and the second flow guiding unit is disposed in the water collecting tank.

In the aforementioned immersion cooling system, the first flow guiding unit is in a shape of a triangular body and has a first inclined surface, and the first inclined surface is inclined toward one side of the water collecting tank.

In the aforementioned immersion cooling system, the second flow guiding unit has a second inclined surface, and the second inclined surface is adjacent to one side of the first inclined surface.

In the aforementioned immersion cooling system, the second flow guiding unit is in a shape of a triangular body.

In the aforementioned immersion cooling system, a plurality of the second flow guiding units are arranged up and down in a plurality of columns along a direction of gravity.

In the aforementioned immersion cooling system, the second inclined surfaces of any two of the second flow guiding units in a row are corresponding to each other and have a distance therebetween and are funnel-shaped.

In the aforementioned immersion cooling system, a bottom edge of the second inclined surface of the second flow guiding unit in one row corresponds to a top edge of the second inclined surface of the second flow guiding unit in a next row.

In the aforementioned immersion cooling system, the immersion cooling system further comprises at least one valve unit disposed on at least one side of the water collecting tank adjacent to the second accommodating space.

In the aforementioned immersion cooling system, the heat dissipation medium defines a horizontal plane, and a position of the valve unit is lower than the horizontal plane.

In the aforementioned immersion cooling system, a part of the flow guiding structure is higher than the horizontal plane and is not located in the heat dissipation medium.

In the aforementioned immersion cooling system, the second accommodating space and the water collecting tank are arranged up and down along a direction of gravity.

To sum up, the immersion cooling system of the present disclosure is provided with a flow guiding structure, which can increase the speed of separation of the heat dissipation medium and water, reduce the time for the heat dissipation medium and water to separate to a stable state, and can effectively discharge water in the heat dissipation medium. Therefore, the evaporation and condensation efficiency will not be reduced, and the chance of equipment damage is small.

### BRIEF DESCRIPTION OF THE DRAWINGS

FIG. 1 is a three-dimensional schematic view of an immersion cooling system according to the present disclosure.

FIG. 2 is a three-dimensional schematic view of the immersion cooling system according to the present disclosure from another perspective.

FIG. 3 is a schematic cross-sectional view of a side of the immersion cooling system according to the present disclosure.

FIG. 4 is a schematic cross-sectional view of a back of the immersion cooling system according to the present disclosure.

### DETAILED DESCRIPTION

The following describes the implementation of the present disclosure with examples. Those skilled in the art can easily understand other advantages and effects of the present disclosure from the contents disclosed in this specification, and can implement or apply the present disclosure via other different embodiments.

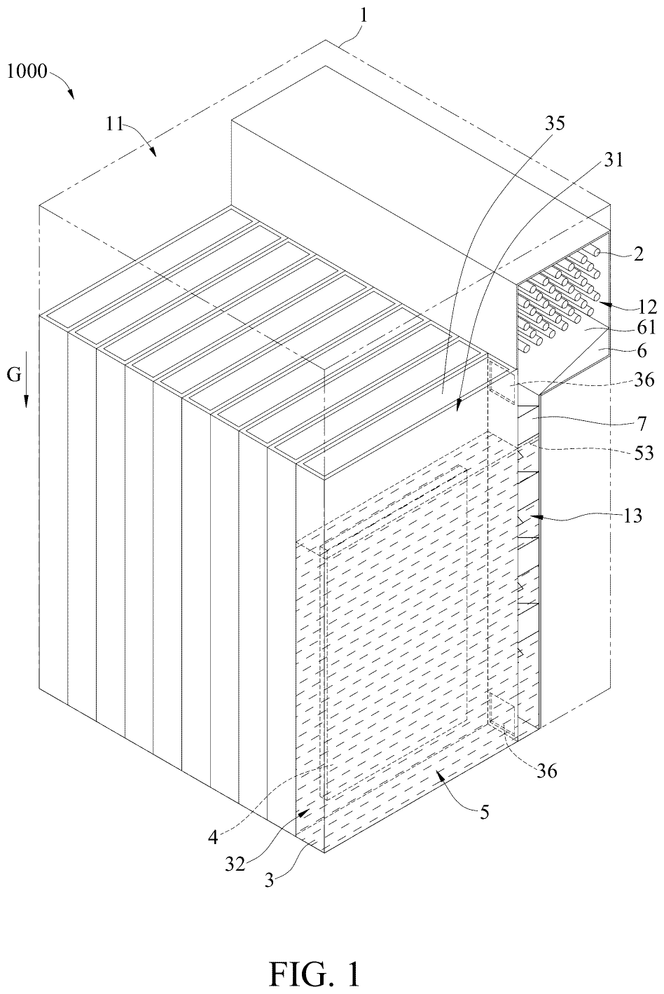

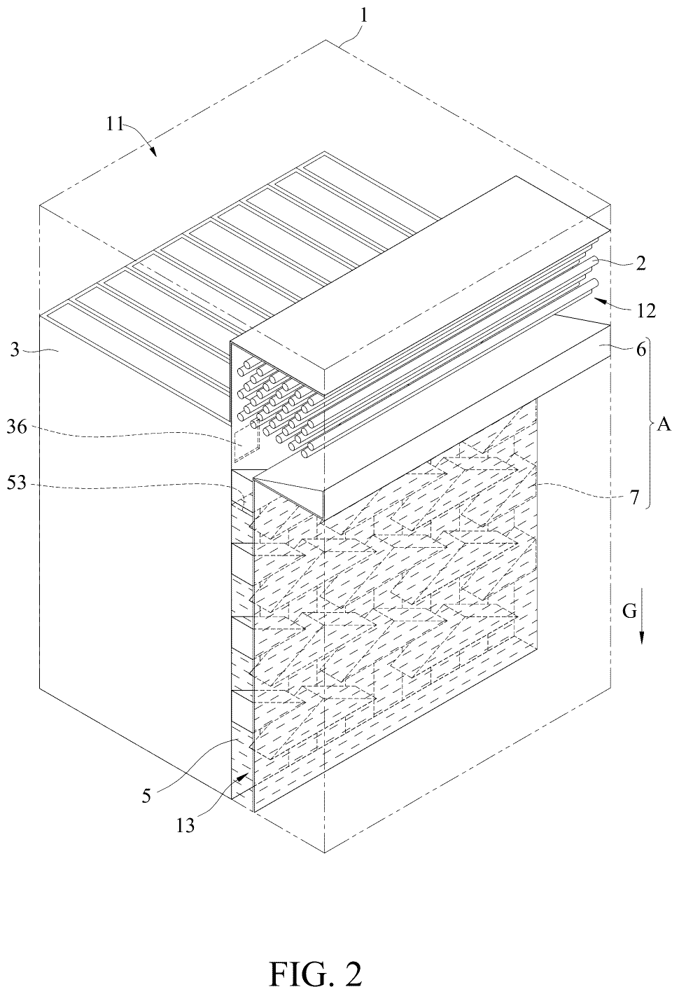

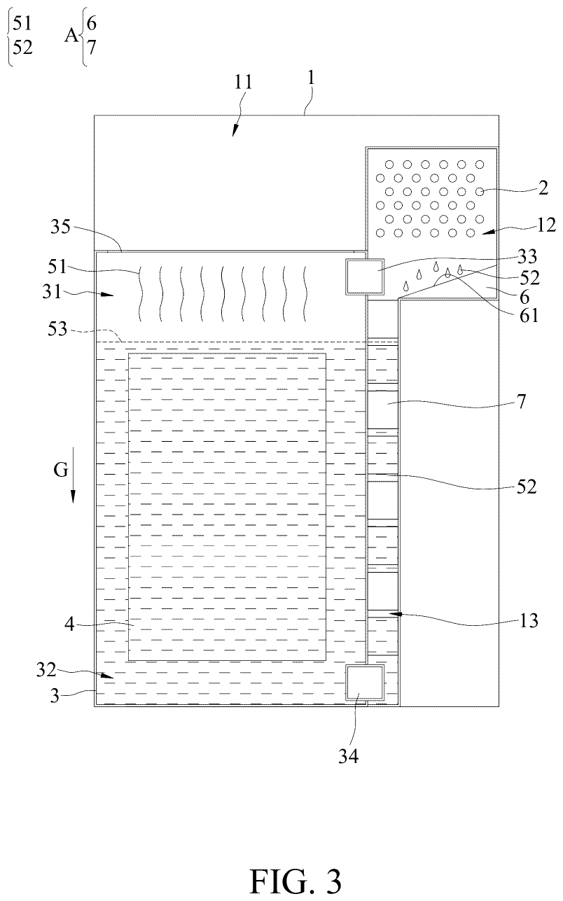

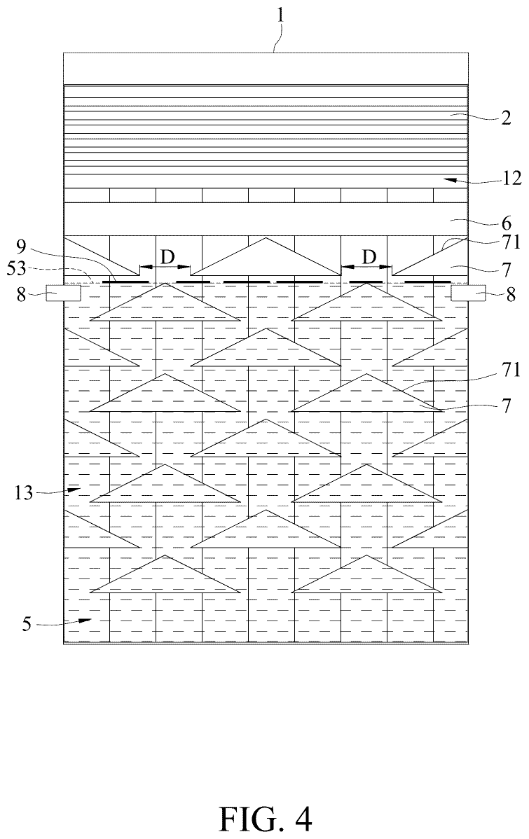

Referring to FIG. 1, FIG. 2 and FIG. 3, an immersion cooling system 1000 of the present disclosure includes a box body 1, a condensing unit 2, a plurality of tank bodies 3, a flow guiding structure A and at least one valve unit 8 (as shown in FIG. 4). The structure of each element and the connection relationship between each other will be described in detail below, wherein some figures show the direction of gravity G.

The box body 1 can specifically be a two-phase immersed cooling positive high-pressure sealed tank, and the two-phase immersed cooling positive high-pressure sealed tank has a first accommodating space 11, a second accommodating space 12 and a water collecting tank 13 defined therein. The first accommodating space 11 and the second accommodating space 12 or the water collecting tank 13 can be separated from each other by partitions or the plurality of tank bodies 3, while the second accommodating space 12 is connected to the water collecting tank 13. In one embodiment, the second accommodating space 12 and the water collecting tank 13 are arranged up and down along the direction of gravity G, and the first accommodating space 11 is located on one side of the second accommodating space 12 and the water collecting tank 13.

The condensing unit 2 is arranged in the second accommodating space 12. In one embodiment, the condensing unit 2 may be a condenser, such as a U-shaped condenser, a straight condenser, or a serpentine condenser, wherein both ends of the condenser can be connected to a loop-shaped pipe, and a heat exchange device (such as a heat pipe), a water-cooling radiator (such as a fan), and a pump can be disposed on the loop-shaped pipe, and wherein the pump can drive the water-cooling liquid in the condenser and the loop-shaped pipe.

The plurality of tank bodies 3 are each roughly in the shape of a rectangular parallelepiped, and are arranged side by side in the first accommodating space 11 along a direction perpendicular to the direction of gravity G, thereby separating the first accommodating space 11 and the water collecting tank 13. In other embodiments, the first accommodating space 11 and the water collecting tank 13 can also be separated by a partition first. At this time, the partition needs to have openings for a first valve member 33 and a second valve member 34 to pass through, but the present disclosure is not limited to as such.

Each tank body 3 is independent and has a vapor space 31 and a liquid storage space 32 connected to the vapor space 31 defined therein. Two openings 36 can be opened on one side plate separating the first accommodating space 11 and the water collecting tank 13. The two openings 36 are used to install the first valve member 33 and the second valve member 34 respectively (the first valve member 33, the second valve member 34 and the valve unit 8 are omitted in FIG. 1 and FIG. 2 for a clearer illustration). One opening 36 is close to the top side of each tank body 3, and the other opening 36 is close to the bottom side of each tank body 3, so that the first valve member 33 and the second valve member 34 are arranged up and down along the direction of gravity G, and the first valve member 33 and the second valve member 34 respectively correspond to the upper and lower sides of the water collecting tank 13.

The vapor space 31 and the liquid storage space 32 are arranged up and down along the direction of gravity G. The vapor space 31 is connected to the first valve member 33 to accommodate a gasified heat dissipation medium 51. The liquid storage space 32 is connected to the second valve member 34 and is used to accommodate a liquefied heat dissipation medium 52. The liquid storage space 32 in each tank body 3 can be provided with a heating unit 4, and the heating unit 4 can be immersed in the liquefied heat dissipation medium 52. In one embodiment, the boundary between the vapor space 31 and the liquid storage space 32 can be determined by the liquefied heat dissipation medium 52. As long as the heating unit 4 can be completely immersed in the liquefied heat dissipation medium 52, a horizontal plane 53 of the liquefied heat dissipation medium 52 is the boundary, and the boundary is generally adjacent to but not in contact with the first valve member 33.

In one embodiment, the first valve member 33 is a one-way valve, which allows the vapor space 31 and the second accommodating space 12 to be connected to each other. The second valve member 34 is a three-way valve, which allows the liquid storage space 32 and the water collecting tank 13 to be connected to each other, and can also be connected to a backup side tank. By controlling the second valve member 34, the liquid storage space 32 and the water collecting tank 13 can be connected to each other, but not connected to the backup side tank, or the liquid storage space 32 and the backup side tank can be connected to each other, but not connected to the water collecting tank 13, so as to guide a heat dissipation medium 5 to a desired space.

In other embodiments, the second valve member 34 can also be a one-way valve connected to the liquid storage space 32 and the water collecting tank 13, and the second valve member 34 can be changed to be connected to the liquid storage space 32 and the backup side tank when needed, wherein a pump is used to guide the heat dissipation medium 5 from the liquid storage space 32 to the backup side tank.

In one embodiment, the heat dissipation medium 5 can be, for example, non-conductive water-cooling liquid, and the heating unit 4 can be, for example, a 2U server (a server that occupies two units of a standard server rack), wherein there are, for example, central processing units, graphics chips, other types of chips, or other heat sources inside the 2U server that generate heat, but the present disclosure is not limited to as such.

The top side of each tank body 3 may have a cover plate 35 adjacent to the first valve member 33, wherein the cover plate 35 can be used to separate the vapor space 31 and the first accommodating space 11, and can be locked and sealed on the top side of each tank body 3, or can be detached from the top side of each tank body 3. When the cover plate 35 is closed on the top side of one of the tank bodies 3, the vapor space 31 and the liquid storage space 32 are not connected to the first accommodating space 11, and are not connected to the vapor spaces 31 and the liquid storage spaces 32 of other tank bodies 3.

Please refer to FIG. 4 as well. The flow guiding structure A is located below the condensing unit 2. Specifically, the flow guiding structure A includes a first flow guiding unit 6 and at least one second flow guiding unit 7. The first flow guiding unit 6 is arranged in the second accommodating space 12. Specifically, the first flow guiding unit 6 can be in the shape of a triangular body and has a first inclined surface 61, and the first inclined surface 61 is inclined toward one side of the water collecting tank 13, so that the first flow guiding unit 6 does not cover the water collecting tank 13. The first flow guiding unit 6 is used to receive the liquefied heat dissipation medium 52 so that the liquefied heat dissipation medium 52 flows on the first inclined surface 61 and finally flows into the water collecting tank 13. The second flow guiding unit 7 is arranged in the water collecting tank 13. Specifically, the second flow guiding unit 7 can be in the shape of a triangular body and has a second inclined surface 71, and the second inclined surface 71 is adjacent to one side of the first inclined surface 61. The second flow guiding unit 7 is used to receive the liquefied heat dissipation medium 52 flowing out from the first flow guiding unit 6, so that the liquefied heat dissipation medium 52 flows on the second inclined surface 71, and is finally mixed with the liquefied heat dissipation medium 52 in the water collecting tank 13.

In one embodiment, there can be a plurality of the second flow guiding units 7, and the second flow guiding units 7 are arranged up and down along the direction of gravity G in a plurality of columns. For example, eight columns can be configured. Moreover, there may be four second flow guiding units 7 in each column, but the present disclosure is not limited to as such.

In one embodiment, the second inclined surfaces 71 of any two second flow guiding units 7 in each row correspond to each other and have a distance D therebetween and are funnel-shaped, wherein the bottom edge of the second inclined surface 71 of the second flow guiding unit 7 in one row may correspond to the top edge of the second inclined surface 71 of the second flow guiding unit 7 in the next row. This arrangement is to extend the distance that the liquefied heat dissipation medium 52 flows on the second inclined surface 71, but the present disclosure is not limited to as such. As long as the flow distance of the liquefied heat dissipation medium 52 can be lengthened, the configuration of the plurality of second flow guiding units 7 can also be changed from a funnel shape to a flat labyrinth shape, so that the second flow guiding unit 7 is in the shape of a flat plate instead of a triangular body.

In one embodiment, a portion of the second flow guiding units 7 may not be located in the heat dissipation medium 5, and another portion of the second flow guiding units 7 may be located in the heat dissipation medium 5. For example, in FIG. 4, four second flow guiding units 7 are not located in the heat dissipation medium 5, that is, above the horizontal plane 53, while the remaining second flow guiding units 7 are located in the heat dissipation medium 5, but the present disclosure is not limited to as such. The number of the second flow guiding units 7 located in the heat dissipation medium 5 can be reduced according to design requirements.

The valve unit 8 is disposed on one side of the water collecting tank 13 adjacent to the second accommodating space 12, and the position of the valve unit 8 can be lower than the horizontal plane 53. In one embodiment, the valve unit 8 may be a one-way valve.

The immersion cooling system 1000 of the present disclosure operates as follows. The liquefied heat dissipation medium 52 in the liquid storage space 32 gasifies after absorbing the heat energy generated by the heating unit 4, wherein the gasified heat dissipation medium 51 moves to the vapor space 31 and moves to the second accommodating space 12 via the first valve member 33, and wherein, at this time, the condensing unit 2 allows the gasified heat dissipation medium 51 to perform heat exchange. After heat exchange between the water-cooling liquid in the condensing unit 2 and the gasified heat dissipation medium 51, the heated water-cooling liquid will flow along the loop-shaped pipe to the heat exchange device for cooling, and the pump can drive the cooled water-cooling liquid to return to the condensing unit 2 via the loop-shaped pipe for heat exchange in the next cycle. The gasified heat dissipation medium 51 is condensed and liquefied after heat exchange. The liquefied heat dissipation medium 52 drips from the condensing unit 2 to the first flow guiding unit 6, flows on the first inclined surface 61, and is finally introduced into the water collecting tank 13 and falls on the second flow guiding unit 7. Thereafter, the liquefied heat dissipation medium 52 flows on the second inclined surface 71 and is finally mixed with the liquefied heat dissipation medium 52 in the water collecting tank 13. After the liquefied heat dissipation medium 52 flows on the first inclined surface 61 and the second inclined surface 71, the liquefied heat dissipation medium 52 itself can be stratified by gravity and density (the heat dissipation medium 5 is not soluble in water, and the density of the heat dissipation medium 5 is different from water), and water 9 contained in the liquefied heat dissipation medium 52 can be separated. The heat dissipation medium 5 having high density will be in the lower layer, while the water 9 having low density will be in the upper layer. That is, the water 9 will float on the horizontal plane 53. By opening the valve unit 8, the water 9 can be discharged from the water collecting tank 13. Depending on the position of the valve unit 8, a part of the heat dissipation medium 5 may be discharged when the water 9 is discharged. At this time, the discharged water 9 and the heat dissipation medium 5 can be sent to a later stage for separation operation to recover the heat dissipation medium 5. Finally, the liquefied heat dissipation medium 52 can be guided back to the liquid storage space 32 in the tank body 3 via the second valve member 34 for the next heat dissipation cycle.

In one embodiment, the opening timing of the valve unit 8 can be determined by detecting the water concentration of the liquefied heat dissipation medium 52. For example, by setting a threshold value, the valve unit 8 is opened when the value is higher than the threshold value.

The effects of the immersion cooling system of the present disclosure are as follows. When the prior art did not have the flow guiding structure of the present disclosure, the time it took for the liquefied heat dissipation medium and water to separate and stabilize was 51 hours. The time required for the liquefied heat dissipation medium and water in the immersion cooling system of the present disclosure to separate and stabilize is 9 hours.

To sum up, the immersion cooling system of the present disclosure is provided with a flow guiding structure, which can increase the speed of separation of the heat dissipation medium and water, reduce the time for the heat dissipation medium and water to separate to a stable state, and can effectively discharge water in the heat dissipation medium. Therefore, the evaporation and condensation efficiency will not be reduced, and the chance of equipment damage is small.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An immersion cooling system, comprising:
a box body having a first accommodating space, a second accommodating space and a water collecting tank connected to the second accommodating space;
a condensing unit arranged in the second accommodating space;
a flow guiding structure located below the condensing unit; and
a heat dissipation medium accommodated in the first accommodating space and the water collecting tank, wherein the heat dissipation medium absorbs thermal energy in the first accommodating space and then gasifies and is introduced into the second accommodating space, wherein the gasified heat dissipation medium is condensed and liquefied via heat exchange in the condensing unit, and the liquefied heat dissipation medium flows on the flow guiding structure to separate water contained in the liquefied heat dissipation medium.

2. The immersion cooling system of claim 1, wherein the flow guiding structure includes a first flow guiding unit and at least one second flow guiding unit, the first flow guiding unit is disposed in the second accommodating space, and the second flow guiding unit is disposed in the water collecting tank.

3. The immersion cooling system of claim 2, wherein the first flow guiding unit is in a shape of a triangular body and has a first inclined surface, and the first inclined surface is inclined toward one side of the water collecting tank.

4. The immersion cooling system of claim 3, wherein the second flow guiding unit has a second inclined surface, and the second inclined surface is adjacent to one side of the first inclined surface.

5. The immersion cooling system of claim 4, wherein the second flow guiding unit is in a shape of a triangular body.

6. The immersion cooling system of claim 4, wherein a plurality of the second flow guiding units are arranged up and down in a plurality of columns along a direction of gravity.

7. The immersion cooling system of claim 6, wherein the second inclined surfaces of any two of the second flow guiding units in a row are corresponding to each other and have a distance therebetween and are funnel-shaped.

8. The immersion cooling system of claim 6, wherein a bottom edge of the second inclined surface of the second flow guiding unit in one row corresponds to a top edge of the second inclined surface of the second flow guiding unit in a next row.

9. The immersion cooling system of claim 1, further comprising at least one valve unit disposed on at least one side of the water collecting tank adjacent to the second accommodating space.

10. The immersion cooling system of claim 9, wherein the heat dissipation medium defines a horizontal plane, and a position of the valve unit is lower than the horizontal plane.

11. The immersion cooling system of claim 10, wherein a part of the flow guiding structure is higher than the horizontal plane and is not located in the heat dissipation medium.

12. The immersion cooling system of claim 1, wherein the second accommodating space and the water collecting tank are arranged up and down along a direction of gravity.
